(19) United States
(12) Patent Application Publication
(10) Pub. No.: US 2010/0311234 A1
(43) Pub. Date: Dec. 9, 2010

(54) METHOD OF MANUFACTURING SEMICONDUCTOR DEVICE

(75) Inventor: Yukinori Tabira, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/789,957

(22) Filed: May 28, 2010

(30) Foreign Application Priority Data
Jun. 9, 2009 (JP) 2009-138689

(51) Int. Cl. H01L 21/44; B23K 31/02; B23K 37/04; B23K 37/00

(52) U.S. Cl. 438/617; 228/101; 228/49.5; 228/15.1; 257/E21.476

(57) ABSTRACT

A method of manufacturing a semiconductor device is provided. A first bond of a first wire loop is formed. A wire is bonded through a ball to a lead or a chip electrode of a semiconductor chip to form a second bond of the first wire loop and a first bond of a second wire loop. A second bond of the second wire loop is formed. The ball provides a large bonding area, and thus, provides a strong bonding strength.

This application is based upon and claims the benefit of priority from Japanese patent application No. 2009-138689, filed on Jun. 9, 2009, the disclosure of which is incorporated herein in its entirety by reference.

### BACKGROUND OF THE INVENTION

1. Field of the Invention

The present invention relates to a semiconductor device, a method of manufacturing a semiconductor, a wire bonding apparatus, and a method of operating a wire bonding apparatus.

2. Description of Related Art

A method of manufacturing a semiconductor device (a semiconductor package) includes steps of mounting, wire bonding, and molding. In the step of wire bonding, a wire loop is formed to electrically connect between a chip electrode of a semiconductor chip (a semiconductor die) and a lead.

A conventional wire bonding will be described with referring to FIGS. 1A to 1F.

Referring to FIG. 1A, a semiconductor chip 105 and a lead 107 are set on a heater stage 108. The semiconductor chip 105 includes a chip electrode 106. A wire 101 extends from a tip of a capillary 103. By making an electric discharge between a spark rod 104 and an end of the wire 101, the end of the wire 101 is melt to form a ball 102.

Referring to FIG. 1B, the capillary 103 presses the ball 102 onto the chip electrode 106. At this time, a load from the capillary 103, an ultrasonic through the capillary 103, and a heat from the heater stage 108 cause the ball 102 to be bonded to the chip electrode 106. This bonding is referred to as a first bonding of a wire loop 101a. The wire loop 101a will be described later.

Referring to FIG. 1C, through the first bonding of the wire loop 101a, a first bond of the wire loop 101a is formed as a ball bond 101e. After the formation of the first bond of the wire loop 101a, the capillary 103 moves to the lead 107 while feeding the wire 101.

Referring to FIG. 1D, by moving the capillary 103 to the lead 107 while feeding the wire 101, the wire loop 101a is formed in the wire 101.

Referring to FIG. 1E, the capillary 103 presses the wire 101 onto the lead 107. At this time, a load from the capillary 103, an ultrasonic through the capillary 103, and a heat from the heater stage 108 causes the wire 101 to be bonded to the lead 107. This bonding is referred to as a second bonding of the wire loop 101a. In the second bonding of the wire loop 101a, a second bond of the wire loop 101a is formed as a stitch bond 101f. At this time, a tail bond 101g is formed simultaneously.

Referring to FIG. 1F, after moving the capillary 103 upward while feeding the wire 101, releasing the tail bond 101g from the lead 107 by moving the capillary 103 upward with the feed of the wire 101 being stopped by a wire clamper (not shown). At this time, the wire 101 is cut and a wiring is finished.

By the way, there is known a MOSFET (Metal-Oxide-Semiconductor Field-Effect-Transistor) device as a semiconductor device. In order to improve an on-resistance and a forward voltage drop of the MOSFET device, various methods of wire bonding have been developed. For example, a method is developed in which a chip electrode of a semiconductor device and a lead are connected through a plurality of wire loops.

However, down-sizing of a semiconductor device has reduced an area of a chip electrode of the semiconductor chip. Therefore, it is difficult to connect the chip electrode 106 and the lead 107 through a plurality of wire loops by repeating the wire bonding illustrated in FIGS. 1A to 1F. When an area of the chip electrode 106 is small, in a step of adding another wire loop 101a, the capillary 103 may interfere with the wire loop 101a and the ball 102 which have already been formed.

Japanese Examined Patent Publication (JP-B-Heisei 6-66352) discloses a wire bonding which can connect a chip electrode having a small area and a lead through a plurality of wire loops.

FIG. 2 shows wire loops 111 and 112 formed by the wire bonding disclosed in Japanese Examined Patent Publication (JP-B-Heisei 6-66352). The wire loops 111 and 112 connect a chip electrode 116 of a semiconductor chip 115 and a lead 117, respectively.

Referring to FIG. 2, the wire bonding disclosed in Japanese Examined Patent Publication (JP-B-Heisei 6-66352) is described. Firstly, a ball 120 formed at an end of the wire 101 is bonded to the lead 117 so as to form a first bond 111a of the wire loop 111 on the lead 117. After that, the capillary 103 presses the wire 101 onto the chip electrode 116 so as to form a second bond 111b of the wire loop 111 and a first bond 112a of the wire loop 112 on the chip electrode 116. Here, the second bond 111b and the first bond 112a are formed as a stitch bond and a tail bond as described above, respectively. After that, the wire loop 112 is formed without releasing the first bond 112a from the chip electrode 116 and cutting the wire 101. Then, a second bond 112b of the wire loop 112 is formed on the lead 117. The second bond 112b is formed by the same method as illustrated in FIGS. 1E and 1F. Even when an area of the chip electrode 116 is small, the wire bonding can connect the chip electrode 116 and the lead 117 through a plurality of wire loops.

The present inventor has recognized the following problems with respect to the second bond 111b and the first bond 112a. Since the second bond 111b and the first bond 112a have small bonding areas, bonding strengths of the second bond 111b and the first bond 112a are weak. Since the capillary 103 presses the wire 101 directly onto the chip electrode 116, a load from the capillary 103 may damage a circuit of the semiconductor chip 115 beneath the chip electrode 116. Since the second bond 111b is formed on the chip electrode 116 after the formation of the first bond 111a of the wire loop 111 on the lead 117, a height of the wire loop 111 or a distance between the semiconductor chip 115 and the lead 117 is required to be large or long to prevent a short circuit caused by a contact of the wire loop 111 to an edge 115a of the semiconductor chip 115. The large height of the wire loop 111 or the long distance between the semiconductor chip 115 and lead 117 may result in a large size of a semiconductor device which mounts the semiconductor chip 115.

### SUMMARY

In one embodiment, a method of manufacturing a semiconductor device includes: forming a first bond of a first wire loop; bonding a wire through a ball to a lead or a chip electrode of a semiconductor chip to form a second bond of the first wire loop and a first bond of a second wire loop; and forming a second bond of the second wire loop.

In another embodiment, a semiconductor device includes: a semiconductor chip; a lead; and a continuous wire. The wire extends from a first position of the lead by way of a chip electrode of the semiconductor chip to a second position of the lead. The wire is bonded through a first ball to the first position, bonded through a second ball to the chip electrode, and bonded to the second position.

In another embodiment, a semiconductor device includes: a semiconductor chip; a lead; and a continuous wire. The wire extends from a first chip electrode of the semiconductor chip by way of the lead to a second chip electrode of the semiconductor chip. The wire is bonded through a first ball to the first chip electrode, bonded through a second ball to the lead, and bonded through a third ball to the second chip electrode.

In another embodiment, a method of operating a wire bonding apparatus includes: fixing by a clip, a wire extending from a tip of a capillary; forming a bent portion in the wire between the clip and the capillary; melting the bent portion to form a ball on the wire; and

bonding the ball to one of a lead and a chip electrode of a semiconductor chip by using the capillary.

In another embodiment, a wire bonding apparatus includes: a capillary; a clip configured to fix a wire extending from a tip of the capillary; and an energy providing device configured to provide energy to melt the wire to form a ball on the wire.

According to the method of manufacturing a semiconductor device, the semiconductor device, the method of operating a wire bonding apparatus, and the wire bonding apparatus, a large bonding area is provided by the ball, and thus, a strong bonding strength is provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is a side view illustrating a ball formation in a conventional wire bonding;

FIG. 1B is a side view illustrating a first bonding in the conventional wire bonding;

FIG. 1C is a side view illustrating a wire loop formation in the conventional wire bonding;

FIG. 1D is a side view illustrating a second bonding in the conventional wire bonding;

FIG. 1E is an enlarged sectional view of a capillary and illustrates the second bonding in the conventional wire bonding;

FIG. 1F is a side view illustrating a wire cutting in the conventional wire bonding;

FIG. 2 is a side view of a semiconductor device having wire loops formed by a conventional wire bonding;

FIG. 3 is a top view showing a semiconductor device according to a first embodiment in a state after the finish of a wire bonding according to the first embodiment;

FIG. 4A is a side view illustrating the wire bonding according to the first embodiment;

FIG. 4B is a side view illustrating the wire bonding according to the first embodiment;

FIG. 4C is a side view illustrating the wire bonding according to the first embodiment;

FIG. 4D is a side view illustrating the wire bonding according to the first embodiment;

FIG. 4E is a side view illustrating the wire bonding according to the first embodiment;

FIG. 5 is a top view showing a semiconductor device according to a second embodiment in a state during a wire bonding according to the second embodiment; and

FIG. 6 is a side view illustrating a wire bonding according to a third embodiment.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

Referring to attached drawings, a semiconductor device (a semiconductor package), a method of manufacturing a semiconductor device, a wire bonding apparatus, and a method of operating a wire bonding apparatus according to a first embodiment of the present invention will be described.

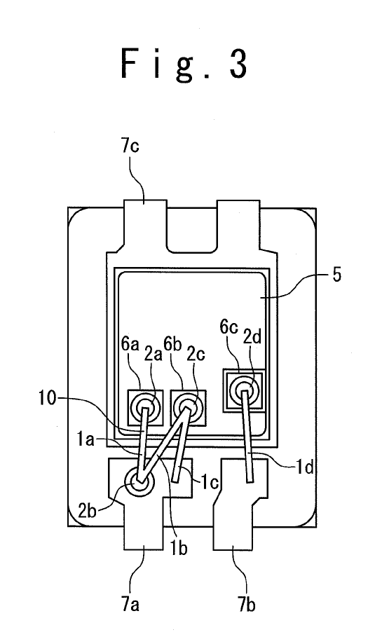

FIG. 3 shows a semiconductor device (a semiconductor package) in a state after the finish of wire bonding. By using an example in which the semiconductor device is a discrete semiconductor, the present embodiment will be described. The semiconductor device according to the present embodiment includes a semiconductor chip (a semiconductor die) 5, a source lead 7a, a gate lead 7b, a drain lead 7c, a wire 10, and a wire loop 1d. Here, the semiconductor chip 5 is a MOSFET chip. The semiconductor chip 5 includes source electrodes (source electrode pads) 6a and 6b, a gate electrode (a gate electrode pad) 6c, and, a drain electrode. The source electrodes 6a and 6b and the gate electrode 6c are formed on a top surface of the semiconductor chip 5. The drain electrode is formed on a bottom surface of the semiconductor chip 5. The drain electrode 5 is bonded directly to the drain lead 7c with conductive bonding material. The source electrodes and the gate electrode may be referred to as chip electrodes (chip electrode pads). The source lead and the gate lead may be referred to as leads.

The wire 10 extends from the source electrode 6a by way of a first position of the source lead 7a and the source electrode 6b in this order to a second position of the source lead 7a. The wire 10 is continuous from the source electrode 6a to the second position of the source lead 7a. The wire is bonded through a ball 2a to the source electrode 6a, bonded through a ball 2b to the first position of the source lead 7a, and bonded through a ball 2c to the source electrode 2b. Therefore, the wire 10 includes a wire loop 1a electrically connecting the source electrode 6a and the first position of the source lead 7a, a wire loop 1b electrically connecting the first position of the source lead 7a and the source electrode 6b, and a wire loop 1c electrically connecting the source electrode 6b and the second position of the source lead 7a. At a first bond of the wire loop 1a, the wire 10 is bonded through the ball 2a to the source electrode 6a. At a second bond of the wire loop 1a and a first bond of the wire loop 1b, the wire 10 is bonded through the ball 2b to the first position of the lead 7a. At a second bond of the wire loop 1b and a first bond of the wire loop 1c, the wire 10 is bonded through the ball 2c to the source electrode 6b. At a second bond of the wire loop 1c, the wire 10 is bonded to the second position of the source lead 7a by stitch bonding.

The wire loop 1d electrically connects the gate electrode 6c and the gate lead 7c. At a first bond of the wire loop 1d, the wire loop 1d is bonded through a ball 2d to the gate electrode 6c. At a second bond of the wire loop 1d, the wire loop 1d is bonded to the gate lead 7b by stitch bonding.

Hereinafter, a wire bonding apparatus, a method of operating the wire bonding apparatus, and a method of manufacturing the semiconductor device according to the present embodiment will be described.

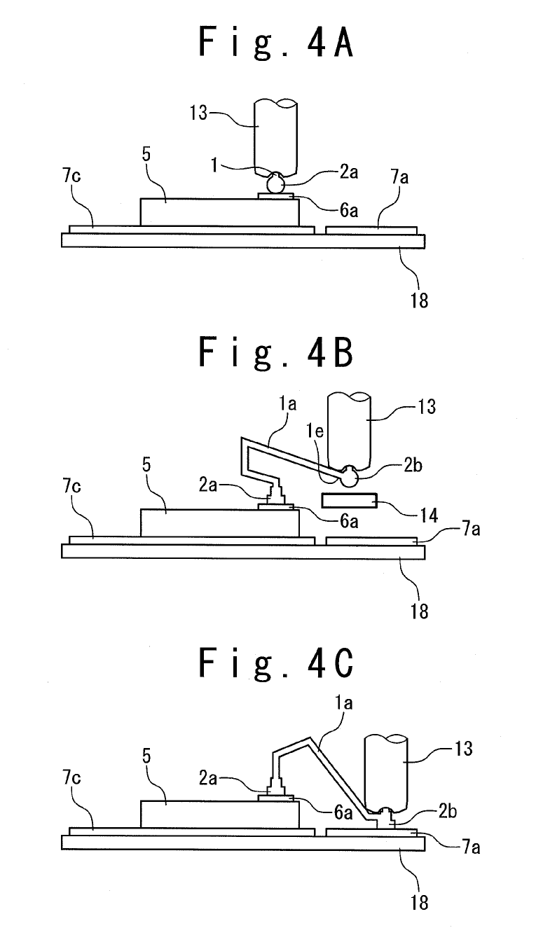

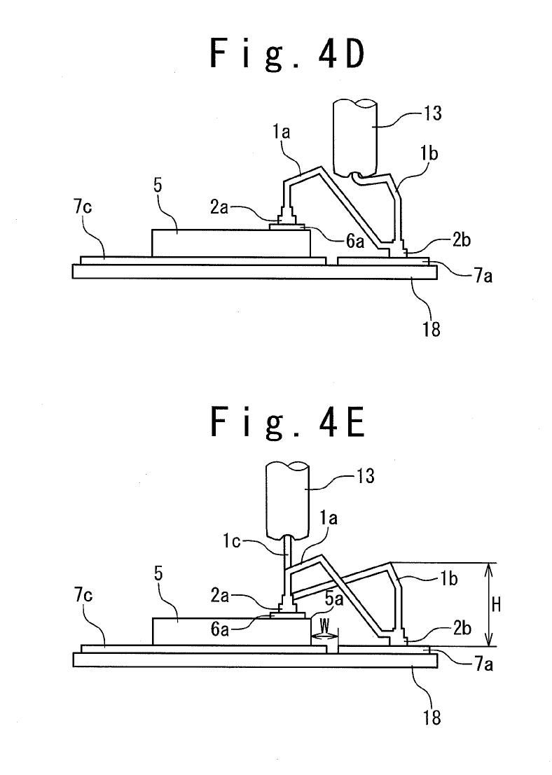

Referring to FIG. 4A, the wire bonding apparatus according to the present embodiment includes a capillary 13, a heater stage 18, and a wire clamper (not shown). The semiconductor chip 5 and the source lead 7a are set on the heater stage 18. A wire 1 extends from a tip of the capillary 13. An end of the wire 1 is melted to form the ball 2a on the wire 1. The capillary 13 presses the ball 2a onto the source electrode 6a. At this time, a load from the capillary 13, an ultrasonic through the capillary 13, and a heat from the heater state 18 cause the ball 2a to be bonded to the source electrode 6a. Accordingly, the wire 1 is bonded through the ball 2a to the source electrode 6a to form the first bond of the wire loop 1a.

Referring to FIG. 4B, the capillary 13 moves while feeding a wire portion 1a of the wire 1 from the tip of the capillary 13 such that the wire portion 1a is formed in a wire loop shape. The wire portion 1a is a portion which forms the wire loop 1a. After that, a middle portion 1e of the wire 1 is fed from the tip of the capillary 13. The middle portion 1e is a portion between the wire portion 1a and a wire portion 1b of the wire 1. The wire portion 1b will be described later. The wire bonding apparatus according to the present embodiment further includes a spark rod 14. By making an electric discharge between the spark rod 14 and the tip of the capillary 13 (or between the spark rod 14 and the middle portion 1e), the middle portion 1e is melt to form the ball 2b on the wire 1.

Referring to FIG. 4C, the capillary 13 presses the ball 2b onto the first position of the source lead 7a. At this time, a load from the capillary 13, an ultrasonic through the capillary 13, and a heat from the heater state 18 cause the ball 2b to be bonded to the first position of the source lead 7a. Accordingly, the wire 1 is bonded through the ball 2b to the first position of the source lead 7a to form the second bond of the wire loop 1a and the first bond of the wire loop 1b.

Referring to FIG. 4D, the capillary 13 moves while feeding the wire portion 1b of the wire 1 from the tip of the capillary 13 such that the wire portion 1b is formed in a wire loop shape. The wire portion 1b is a portion which forms the wire loop 1b. After that, a middle portion of the wire 1 is fed from the tip of the capillary 13. The middle portion is a portion between the wire portion 1b and a wire portion 1c of the wire 1. The wire portion 1c will be described later. By making an electric discharge between the spark rod 14 and the tip of the capillary 13 (or between the spark rod 14 and the middle portion), the middle portion is melt to form the ball 2c on the wire 1.

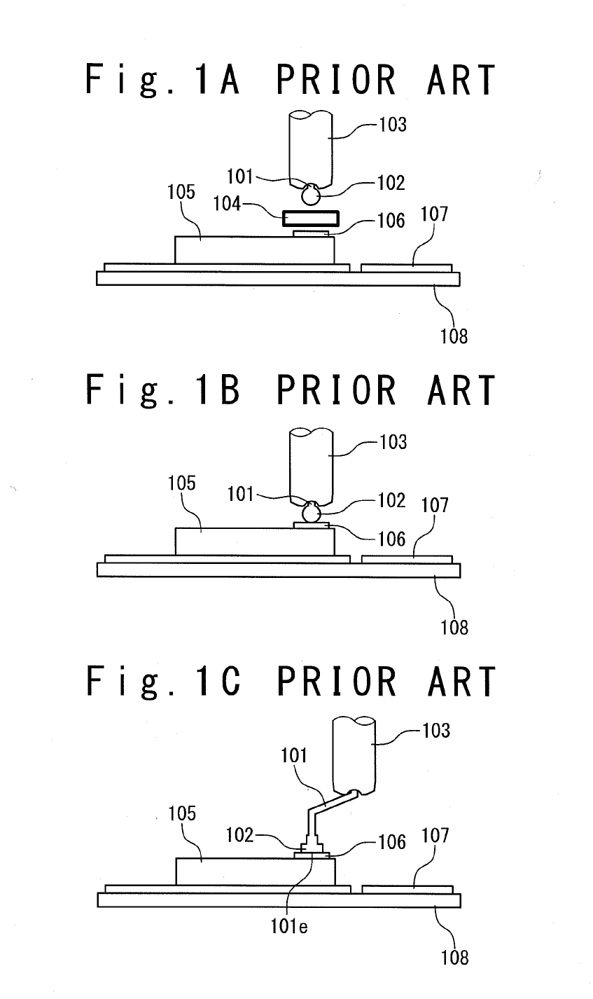

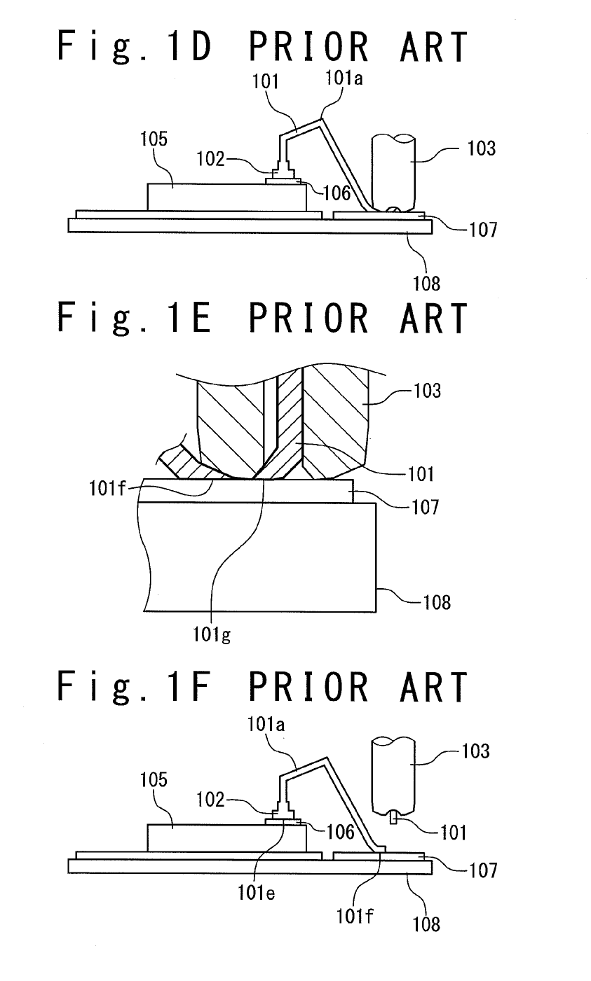

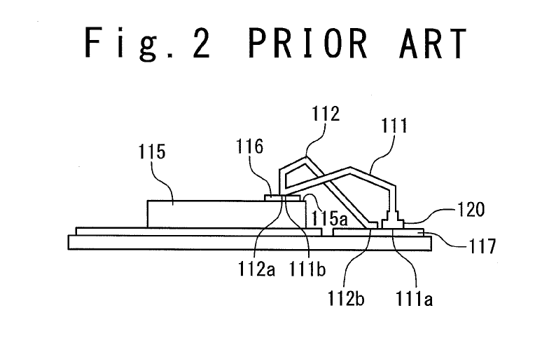

Referring to FIG. 4E, the capillary 13 presses the ball 2c onto the source electrode 6b. At this time, a load from the capillary 13, an ultrasonic through the capillary 13, and a heat from the heater state 18 cause the ball 2c to be bonded to the source electrode 6b. Accordingly, the wire 1 is bonded through the ball 2c to the source electrode 6b to form the second bond of the wire loop 1b and the first bond of the wire loop 1c. Next, the capillary 13 moves while feeding the wire portion 1c of the wire 1 from the tip of the capillary 13 such that the wire portion 1c is formed in a wire loop shape. The wire portion 1c is a portion which forms the wire loop 1c. Next, the wire 1 is bonded to the second position of the source lead 7a by the same as method illustrated in FIGS. 1E and 1F. Accordingly, the second bond of the wire loop 1c is formed as a stitch bond.

It should be noted that the wire bonding apparatus does not cut the wire between the formation of the first bond of the wire loop 1a and the bonding of the wire 1 to the second position of the source lead 7a.

According to the present embodiment, a plurality of wire loops can be bonded to a single chip electrode or a single lead. Furthermore, a large bonding area is provided by the ball, and thus, a strong bonding strength is provided. Furthermore, since the wire is pressed onto the chip electrode through the ball, a circuit of the semiconductor chip 5 beneath the chip electrode is prevented from being damaged. Furthermore, since the wire 1 (or the wire 10) is bonded through the ball 2b to the source electrode 6b, a sufficient clearance can be provided between an edge 5a of the semiconductor chip 5 and the wire loop 1b without making a height H of the wire loop 1b large or making a distance W between the semiconductor chip 5 and the source lead 7a long as illustrated in FIG. 4E.

Therefore, even when the semiconductor device is small in size, a property such as on-resistance and forward voltage drop of the semiconductor device can be improved.

### Second Embodiment

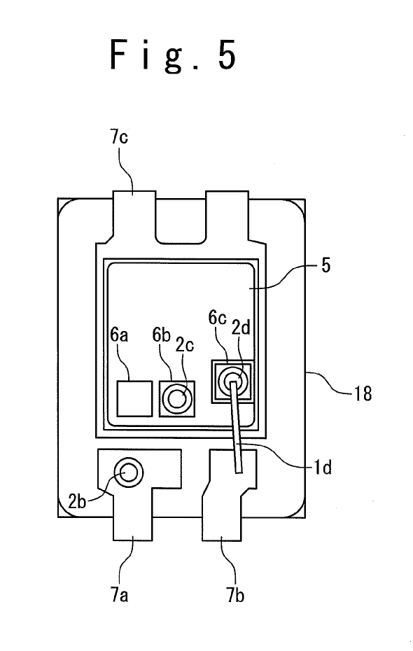

Referring to FIG. 5, a second embodiment of the present invention will be described. In the present embodiment, the ball 2b is formed on the first position of the source lead 7a and the ball 2c is formed on the source electrode 6b in advance. In the present embodiment, the wire 10 is formed by bonding the ball 2a to the source electrode 6a in the same manner as the first embodiment, bonding the wire 1 to the ball 2b, bonding the wire 1 to the ball 2c, and bonding the wire 1 to the second position of the source lead 7a in the same manner as the first embodiment.

According to the present embodiment, since the balls 2b and 2c are formed in advance, the wire 10 is formed in a short time. As a result, a whole throughput of steps of forming the balls 2b and 2c and of forming the wire 10 is improved. In addition, the formation of the balls 2b and 2c can be stabilized.

An alternative method can be considered in which the ball 2a is formed on the source electrode 6a and the ball 2b is formed on the source electrode 6b in advance. Here, the ball 2a and 2c are formed by gold-plating in a wafer process before dicing a wafer to form the semiconductor chip 5. In this method, the wire 10 is formed by bonding the wire 1 to the ball 2a, bonding the ball 2b to the first position of the source lead 7a in the same manner as the first embodiment, bonding the wire 1 to the ball 2c, and bonding the wire 1 to the second position of the source lead 7a in the same manner as the first embodiment. According to this method, a whole throughput of steps of forming the balls 2a and 2c and of forming the wire 10 is improved to a large extent.

### Third Embodiment

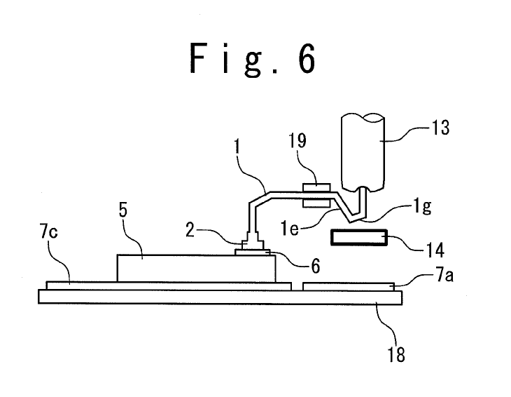

Referring to FIG. 6, a wire bonding apparatus, a method of operating the wire bonding apparatus, and a method of manufacturing the semiconductor device according to a third embodiment of the present invention will be described. The wire bonding apparatus, the method of operating the wire bonding apparatus, and the method of manufacturing the semiconductor device according to the present embodiment are same as those according to the first or second embodiment except the following descriptions.

The wire bonding apparatus according to the present embodiment includes a clip 19. In the method of operating the wire bonding apparatus and the method of manufacturing the semiconductor device, the clip 19 fixes the wire 1 extending from the tip of the capillary 13 such that the middle portion 1e is located between the clip 19 and the tip of the capillary 13, the clip 19 and the capillary 13 forms a bent portion 1g in the middle portion 1e, and the spark rod 14 melts the bent portion 1g to form the ball 2b on the wire 1. The bent portion 1g is formed in a U-shape or a V-shape, for example. The ball 2c is formed in the same manner as the ball 2b.

According to the present embodiment, the wire 1 is prevented from being melt-cut by the shrinkage of the wire 1 in length when the wire 1 is melted to grow the ball 2b or 2c.

The embodiments of the present invention have been described. However, the present invention is not limited to the above embodiments, but may be modified and changed without departing from the scope and spirit of the invention. For example, even when the semiconductor chip 5 includes three or more source electrodes, these source electrodes and the source lead 7a can be electrically connected with a single continuous wire. Moreover, the wire bonding apparatus can include a laser (not shown) in place of the spark rod 14. The laser outputs a laser beam to the wire 1 so as to form the balls 2a, 2b, and 2c. Each of the spark rod 14 and the laser may be referred to as an energy providing device which provides energy to melt the wire 1 to form the ball.

What is claimed is:

1. A method of manufacturing a semiconductor device comprising:
forming a first bond of a first wire loop;
bonding a wire through a ball to a lead or a chip electrode of a semiconductor chip to form a second bond of said first wire loop and a first bond of a second wire loop; and
forming a second bond of said second wire loop.

2. The method of manufacturing a semiconductor device according to claim 1, wherein said wire includes:
a first portion which forms said wire loop;
a second portion which forms said wire loop; and
a middle portion between said first portion and said second portion,
further comprising melting said middle portion to form said ball on said wire.

3. The method of manufacturing a semiconductor device according to claim 2, further comprising:
fixing said wire by the clip; and
forming a bent portion in said middle portion by using said clip,
said bent portion is melt in said melting said middle portion.

4. The method of manufacturing a semiconductor device according to claim 1, further comprising forming said ball on said chip electrode or said lead, and
wherein said wire is bonded to said ball in said bonding said wire.

5. The method of manufacturing a semiconductor device according to claim 1, further comprising:
bonding said wire through a ball to said lead to form said second bond of said second wire loop and a first bond of a third wire loop;
bonding said wire through a ball to another chip electrode of said semiconductor chip to form a second bond of said third wire loop and a first bond of a fourth wire loop; and
forming a second bond of said fourth wire loop on said lead,
wherein said wire is bonded through a ball to said lead in said forming said first bond of said first wire loop, and
said wire is bonded to said chip electrode to form said second bond of said first wire loop and said first bond of said second wire loop.

6. A method of operating a wire bonding apparatus comprising:
fixing by a clip, a wire extending from a tip of a capillary;
forming a bent portion in said wire between said clip and said capillary;
melting said bent portion to form a ball on said wire; and
bonding said ball to one of a lead and a chip electrode of a semiconductor chip by using said capillary.

7. The method of operating a wire bonding apparatus according to claim 6, further comprising:
feeding said wire from said tip of said capillary after said bonding said ball; and
bonding a fed portion of said wire, which is fed in said feeding said wire, to another of said lead and said chip electrode,
wherein said wire is not cut between said bonding said ball and said bonding said fed portion.

8. A wire bonding apparatus comprising:
a capillary;
a clip configured to fix a wire extending from a tip of said capillary; and
an energy providing device configured to provide energy to melt said wire to form a ball on said wire.

9. The wire bonding apparatus according to claim 8, wherein said clip and said capillary are configured to form a bent portion in said wire between said clip and said capillary, and
said energy providing device melts said bent portion to form said ball.
